(19) United States
(12) Patent Application Publication
(10) Pub. No.: US 2011/0253205 A1
(43) Pub. Date: Oct. 20, 2011

(54) Nanoscale Solar Cell Configuration

(75) Inventors: Jeffrey C. Grossman, Brookline, MA (US); Alexander K. Zettl, Kensington, CA (US)

(73) Assignee: The Regents of the University of California

(21) Appl. No.: 13/121,174

(22) PCT Filed: Sep. 25, 2009
(86) PCT No.: PCT/US09/58319

§ 371 Date: Jul. 1, 2011

Related U.S. Application Data
(60) Provisional application No. 61/100,720, filed on Sep. 27, 2008.

(51) Int. Cl. H01L 51/46; H01L 31/06; H01L 31/02; B82Y 99/00

(52) U.S. Cl. 136/255; 438/88; 257/E31.11; 977/762; 977/742; 977/948

(57) ABSTRACT

The present disclosure is directed to an optimized structure for an exciton-based photovoltaic cell, in which the bulk heterojunction between the electron donor (typically an organic polymeric semiconductor) and an electron acceptor (e.g., silicon or titanium or titania) minimizes the necessary exciton travel distance to the heterojunction in three dimensions. The configuration is arrayed in three dimensions, such that one member of the heterojunction pair, such as the electron acceptor is in the form of a number of nanoscale channels, extending to an electrode. The channels extend through a photovoltaic matrix material in a predetermined three-dimensional configuration.

### RELATED APPLICATIONS

This application is the national phase application of International application number PCT/US2009/058319, filed Sep. 25, 2009, which claims priority to and the benefit of U.S. Provisional Application No. 61/100,720, filed on Sep. 27, 2008, which is hereby incorporated by reference in its entirety.

### STATEMENT OF GOVERNMENTAL SUPPORT

This invention was made with government support under Contract No. DE-AC02-05CH11231 awarded by the U.S. Department of Energy and under National Science Foundation COINS Grant No. EEC-0425914. The government has certain rights in the invention.

### FIELD OF THE INVENTION

The present invention relates to the field of composite materials, and more particularly to the field of composite materials having a particular three-dimensional design, for use in solar cells.

### BACKGROUND OF THE INVENTION

Presented below is background information on certain aspects of the present invention as they may relate to technical features referred to in the detailed description, but not necessarily described in detail. That is, certain components of the present invention may be described in greater detail in the materials discussed below. The discussion below should not be construed as an admission as to the relevance of the information to the claimed invention or the prior art effect of the material described.

Existing types of solar cells may be divided into two distinct classes: conventional solar cells, such as silicon p-n junctions, and excitonic solar cells, (“ESCs”). Most organic-based solar cells, including dye-sensitized solar cells, fall into the category of ESCs. In these cells, excitons are generated upon light absorption, and if not created directly at the heterointerface as in dye-sensitized solar cells, they must diffuse to it in order to photogenerate charge carriers.

Excitonic solar cells are made from organic compounds, dyes, gels or liquids, rather than the conventional silicon. Organic semiconductor devices are inherently much less expensive to manufacture, but less efficient due to low charge mobility in the polymer. The most common strategy for making more efficient organic photovoltaics is to use a bulk junction in which excitons coupled electron-hole pairs) are split at an interface between two semiconductors with offset energy levels. In traditional semiconductor theory, materials for forming photovoltaic hetero have been denoted as generally being of either n, or donor, type or p, or acceptor, type. Here n-type denotes that the majority carrier type is the electron.

Since excitons only diffuse 4-20 nm in most organic semiconductors, the interface must be patterned at this scale. Conventional designs of excitonic solar cells, typically based on a blend of electron- and hole-conducting materials, may be layered sheets, unpatterned blends, or may be based on a so-called “ideal” bulk heterojunction, discussed below. In any design, the electron carrier material could be any semi-conductor with the right energy levels, and is typically inorganic. Ideally this would be something inexpensive such as titanium or titania, but silicon is also used. The hole carrier chosen is a polymer that conducts charge. The long chains of polymers enable them to efficiently conduct a charge along their lengths.

In one “ideal” structure, which is largely hypothetical, the n-type and p-type materials are arranged so that one material (typically the n-type, i.e., electron carrying material) forms vertical columns, as shown in prior art FIG. 1. In this type of structure, the columns must have the appropriate aspect ratio such that they are “tall” enough to absorb the light (this depends on the penetration depth of the material), and yet narrow enough so that the excitons formed when light is absorbed can reach an interface (between materials 18 and 20 as shown in prior art FIG. 1) before recombining, which depends on the exciton lifetime and diffusion distance.

Referring to prior art FIG. 1, a photovoltaic cell 12 is shown with a top electrode of indium tin oxide (ITO) 14, a bottom electrode of aluminum 16, and an electron accepting material 18, such as an inorganic nanocomposite, arranged in columns, which could be a sectional view of a pore. A filler of polymer material 20 as an electron donor material is between the columns, i.e., inside and outside of any defined columns or pores. When light 22 enters the photocell, an exciton diffusing in a direction towards electron accepting material 18 will travel a short, predetermined distance, as shown at 24 and 26. The distance between columns of electron accepting material 18 is typically about 20 nm, as indicated by arrow 29. But, an exciton diffusing in the direction of 24, i.e., toward the top or bottom electrode 14, 16, will become extinguished before reaching the electron acceptor. Thus, if an exciton diffuses vertically, it will not reach a contact. Thus this design can only be ideal in two out of three dimensions. The depth of the solar cell, between facing electrode surfaces, indicated by arrow 27, is typically 100-200 nm, defining the absorption depth. Furthermore, in real blended systems, the morphology is much more irregular than is illustrated in prior art FIG. 1. The actual structures resemble a “spaghetti” blend of the two materials. This uncontrolled morphology leads to other problems, such as shorting and interface electronics.

Therefore, the present invention provides a controlled repeating structure that has domains, which lead an exciton to an interface in all three dimensions, minimizing exciton recombination and maximizing photovoltaic conversion efficiency.

### Specific Patents and Publications

Miller et al., “Ordered Nanostructures for Organic Photovoltaic Cells,” 2004 NNIN REU Research Accomplishments, pp. 80-81 discloses a technique for nanoscale lithography to achieve the above described “ideal” structure.

U.S. Pat. No. 5,800,794 to Tanigaki, et al, issued Sep. 1, 1998, entitled “Clathrate compounds and processes for production thereof,” discloses a silicon clathrate compounds encapsulating alkaline earth metals. The clathrates include, as the structural units of crystals, Si₄₆ clusters, each of which consists of Si₂₀ clusters and Si₂₄ clusters with cage structures formed by silicon atoms as the framework of the crystal and at least part of said Si₂₄ clusters encapsulate alkaline earth metal atoms inside the cage, and at least part of the Si₂₀ clusters encapsulate Li₄ inside the cage.

Nolas et al., Clathrate Compounds and Methods of Manufacturing, WO 2007/047952, published 26 Apr. 2007, describes the fabrication of a clathrate compound comprising a type II clathrate lattice with atoms of silicon and germanium as a main framework forming lattice spacings within the framework, wherein the clathrate lattice follows the general formula Si_{136-y} Ge_{y}, where y indicates the number of Ge atoms present in the main framework and 136-y indicates the number of Si atoms present in the main framework, and wherein y>0. This structure allows for the formation of alloys in the main framework of the structure. Specifically, Si—Ge alloys of the general type are formed in accordance with this publication. For the conversion of light to electricity, these alloys are said to show superior performance over either pristine Si or Ge type II clathrate frameworks, in as much as the Si—Ge alloy type II clathrates possess a direct band gap in the electronic band structure, in the visible light range, whereas the pristine clathrates possess indirect band gaps. No particular structure embodying these materials is disclosed.

Sirichantaropass et al., “Electronic Properties of Alkali- and Alkaline-Earth-Intercalated Silicon Nanowires,” Condensed Mat Sci. Phys. Rev. B 75, 075328 (2007) discloses ab initio theoretical studies of the electronic properties of Si(30) Si (36) nanowires intercalated with the alkali- and alkaline-earth metals (Li, Na, K, Rh, Co, Fr) and (Be, Mg, Cu, Sr, Ba, Ra), respectively, which correspond to typical clathrate intercalations.

U.S. Pat. No. 7,238,594 to Fonash, et al., issued Jul. 3, 2007, entitled “Controlled nanowire growth in permanent, integrated nanotemplates and methods of fabricating sensor and transducer structures,” discloses a method to form uniform nanostructures using a nanochannel template. Thus completed devices such as diodes, transistors, solar cells, sensors, and transducers are fabricated.

U.S. Pat. No. 7,291,782 to Sager, et al., issued Nov. 6, 2007, entitled “Optoelectronic device and fabrication method,” discloses an optoelectronic device which may include a porous nano-architected (e.g., surfactant-templated) film having interconnected pores that are accessible from both the underlying and overlying layers. A pore-fitting material substantially fills the pores. The interconnected pores have diameters of about 1-100 nm and are distributed in a substantially uniform fashion with neighboring pores separated by a distance of about 1-100 nm. The nano-architected porous film and the pore-filling, material have complementary charge-transfer properties with respect to each other, i.e., one is an electron-acceptor and the other is a hole-acceptor.

### SUMMARY OF THE INVENTION

The following brief summary is not intended to include all features and aspects of the present invention, nor does it imply that the invention must include all features and aspects discussed in this summary.

The present invention is directed to an optimized structure for an exciton-based photovoltaic cell, in which the bulk heterojunction between the electron donor (typically an organic polymeric semiconductor) and an electron acceptor silicon or titanium or titania) is constructed to minimize the necessary exciton travel distance to the heterojunction in three dimensions. In one embodiment, the photovoltaic cell comprises rod-like structures in a particular crisscross pattern. In this construction, the “vertical” dimension, i.e., the direction of incoming light, is interrupted in portions by angular rods, as opposed to the “hairbrush” structure of the rod-like structures in prior art configurations.

In another embodiment, the photovoltaic cell comprises a plurality of void bearing molecules disposed in the polymer matrix and serving to provide the heterojunction. These molecules are typically clathrate structures that have a three dimensional cage-like structure. The clathrates may be grown around rods or may themselves be electron acceptors or donors. The clathrates may be etched out of solid materials and then filled with polymer. One suitable solid material is aluminum oxide. Another suitable material is comprised of metal-organic frameworks (MOFs). MOFs are crystalline materials composed of metal ions or clusters connected by way of organic linkers. MOB may be self assembled and provided with internal atoms, which act as electron acceptors.

Another suitable class of materials for forming the present material comprises those materials known as zeolites. Zeolites are hydrated aluminosilicate minerals and have a micro-porous structure. These materials act as molecular sieves, and again may be etched and fitted with acceptor materials.

Thus the present invention comprises in certain aspects a design for an excitonic solar cell, where the travel distance required for at least one member of the exciton pair is significantly improved. As is known, the excitonic solar cell has a heterojunction between donor and acceptor semiconductor materials, wherein one semiconductor material is in the form of a matrix material and the other semiconductor material is in the form of a nanoscate channel material contacting an electrode. U.S. Pat. No. 6,900,479 to DeHon, et al., issued May 31, 2005, further describes methods for forming arrays of crossed conductors, which may be adapted according the present teachings to arrays of crossed semiconducting channels.

This patent refers to the stochastic assembly of sublithographic nanoscale interfaces. In the present invention, the nanoscale semiconducting channels extend through the photovoltaic matrix material as separated channel elongated structures along three dimension, which may be oblique or orthogonal to each other and may be termed an X axis, a Y axis and a Z axis, in a three dimensional array which minimizes diffusion distance of a member of an exciton pair formed in the matrix by incoming light. Orthogonal and oblique arrays are illustrated in FIG. 3 and FIG. 2, respectively. The nanoscale channel materials may be of different dimensions, e.g. different diameters, and may be of different materials, e.g. channel materials 304, 302 and 306 as illustrated in FIG. 3, may be of different materials and dimensions. For example, materials in the X direction may be thinner, as in the case where light is incident in that direction. The channel-elongated structures may be carbon nanotubes, including single-walled nanotubes (SWNTs) and multi-walled nanotubes (MWNTs), nanowires, semiconductor nanorods, including semiconductor nanorods such as CdSe, other carbon nanorods, or fullerene and fullerene derivatives such as [6,6]-phenyl-C₆₁-butyric acid methyl ester (PCBM). The fullerenes will be aggregated in the form of elongated structures.

In some cases, the channel-elongated structures (channel members) may provide support for the active semiconducting element. These embodiments are referred to for convenience as clathrate embodiments, and the channel members comprise void bearing molecules. In certain embodiments of the invention, the void bearing molecules provide structural support to channel members, which, again, act as electron or hole carrying elements in the photovoltaic cell. In other embodiments, the void bearing molecules are themselves channel members, e.g., by being made of silicon containing material. The void material in fact may, in certain embodiments, be selected from the group consisting of metal organic framework (MOF), zeolites, silicon clathrates including Si₃₄, Si₂₄ and Si₄₆, and carbon clathrates including C₄₆, C₂₄, C₂₈ and C₃₄. These clathrates are further described in U.S. Pat. No. 6,461,581, issued Oct. 8, 2002. The MOF will comprise a metal, which may be selected from the group consisting of Zn, Cu and Ti. A number of MOFs are known; in one embodiment the MOF is MOF-5. The matrix material may be a polymer, including a conjugated conducting polymer, and may be selected from poly(2-methoxy-5-(3′,7′-dimethyloctyloxy)-1,4-phenylenevinylene) (MDMO-PPV), poly(3-hexylthiophene) (P3HT), 3,4,9,10-perylenetetracarboxylic bisbenzimidazole (PTCBI) or poly(dhododiacetylene) (PIDA).

The present invention further comprises methods of making the present nanoscale solar cell, with improved configuration of the heterojunction. One inventive method comprises aligning channel members by applying to a fluid composition of the members an external electromagnetic field, which orients the members in a defined direction; and solidifying the fluid composition to fix the channel members in the defined direction. Steps (a) and (b) are repeated in different defined directions. One may thus see that different parallel arrays are formed in layers, each layer comprising a set of parallel channels, and each layer having the axis of the channels rotated a certain degree (e.g., 60-90 degrees). The channels may be suspended in a fluid while the field is applied; the fluid is then removed and the nanostructures are fixed in place within a binder or by direct attachment to the substrate. The field may be either electric or magnetic, i.e., electromagnetic. The electromagnetic field may be either a DC or an AC field. As before, the channels may be nanotubes, nanowires, and nanorods. An exemplary channel is a SWNT or MWNT.

### BRIEF DESCRIPTION OF THE DRAWINGS

FIG. 1 is a schematic drawing of a prior art excitonic solar cell configuration.

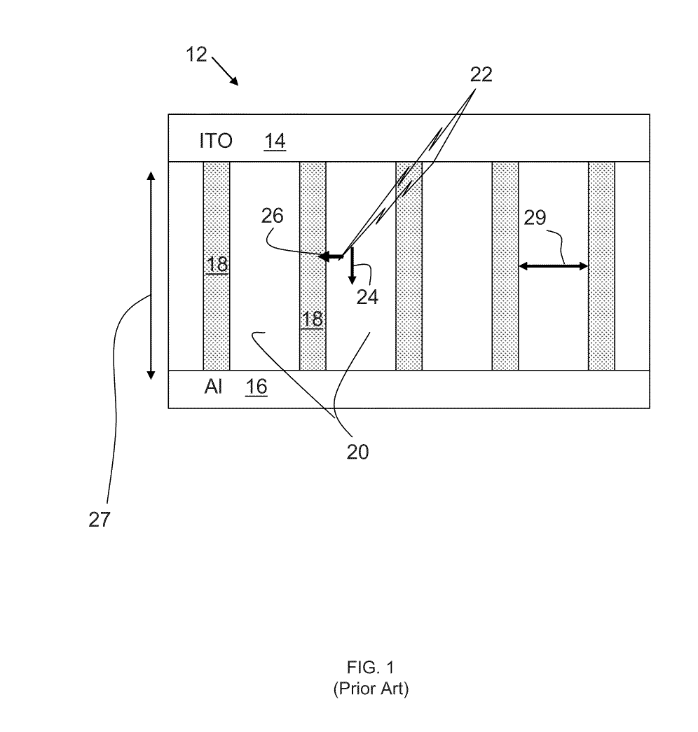

FIG. 2 is schematic drawing of a photovoltaic crisscross geometry according to the present invention, wherein cross member channels are angled relative to a grid of channels.

FIG. 3 is a schematic drawing of an end view of a crisscross geometry according to the present invention, wherein cross member channels are orthogonal to a grid of channels.

FIG. 4 is a schematic drawing of a clathrate structure in three dimensions.

FIG. 5 is a photograph drawing of a clathrate structure in two dimensions.

FIG. 6 is a structural representation of a fullerene derivative useful in forming channels in the present invention.

### DETAILED DESCRIPTION OF THE INVENTION

### Definitions

Unless defined otherwise, all technical and scientific terms used herein have the same meaning as commonly understood by those of ordinary skill in the art to which this invention belongs. Although any methods and materials similar or equivalent to those described herein can be used in the practice or testing of the present invention, the preferred methods and materials are described. Generally, nomenclatures utilized in connection with, and techniques of, physical and materials science are those well known and commonly used in the art. Certain experimental techniques, not specifically defined, are generally performed according to conventional methods well known in the art and as described in various general and more specific references that are cited and discussed throughout the present specification. For purposes of the clarity, following terms are defined below.

The term “excitonic solar cell” is used in its conventional sense to mean a photovoltaic device which employs an electron and an imaginary particle called an electron hole, which exists in an insulator or semiconductor. This is a Coulomb-correlated electron-hole pair, one member of which is the electron, the other member of which is the hole.

The term “nanoscale” is used in a conventional sense, as given in the above-mentioned U.S. Pat. No. 6,900,479, i.e. to dimensions that range from 0.1 nanometers to 50 nanometers (0.05 micrometer), the preferred range being from 0.5 nanometers to 5 nanometers. As described, the present cells may have an absorption depth of 100-200 nm, or longer if the improved heterojunctions described here are employed.

### Overview

Excitonic solar cells, which rely on exciton dissociation at a donor-acceptor interface to create carriers, have recently reached certified solar efficiencies of 5%. Improvements in material quality, device design, and understanding of the device physics have resulted in these increased efficiencies. Organic semiconductors are attractive for use in excitonic solar cells because of the inherent low materials cost and low-energy, high-throughput processing technologies, and because of the huge variety of possible organic systems. The highest-certified organic photovoltaic efficiencies so far come from polymer-fullerene blend devices. Other materials useful in the presently disclosed designs have been demonstrated or envisioned, including evaporated small-molecule devices, polymer-polymer blends, dendrimer-fullerene blends, and hybrid nanocrystalline oxide-polymer composites. The limitations to the efficiency of these photovoltaic cells are generally understood (e.g., the optical bandgap is too high; the band offset between donor and acceptor is not optimized; charge transfer, transport, and recombination are not optimized), but a rigorous fundamental understanding of these issues has not been obtained.

The present invention addresses the need for improved charge transport and concerns a structured configuration for organic/nanomaterial hybrid solar cells that maximizes conversion efficiency by increasing the chance that excitons will reach an interface before recombining. The new geometry will vastly reduce the possibility of electrical shorting and minimize the interface electronics problems encountered when irregular blend morphologies are employed. A variety of electron donor (e.g., polymer) polymer and electron acceptor (e.g., nanocomposite) materials can be used in this invention and both the donor and acceptor materials can be optically absorbing for higher efficiency.

### Crisscross Geometry (Crisscrossed Channel-Like Structures)

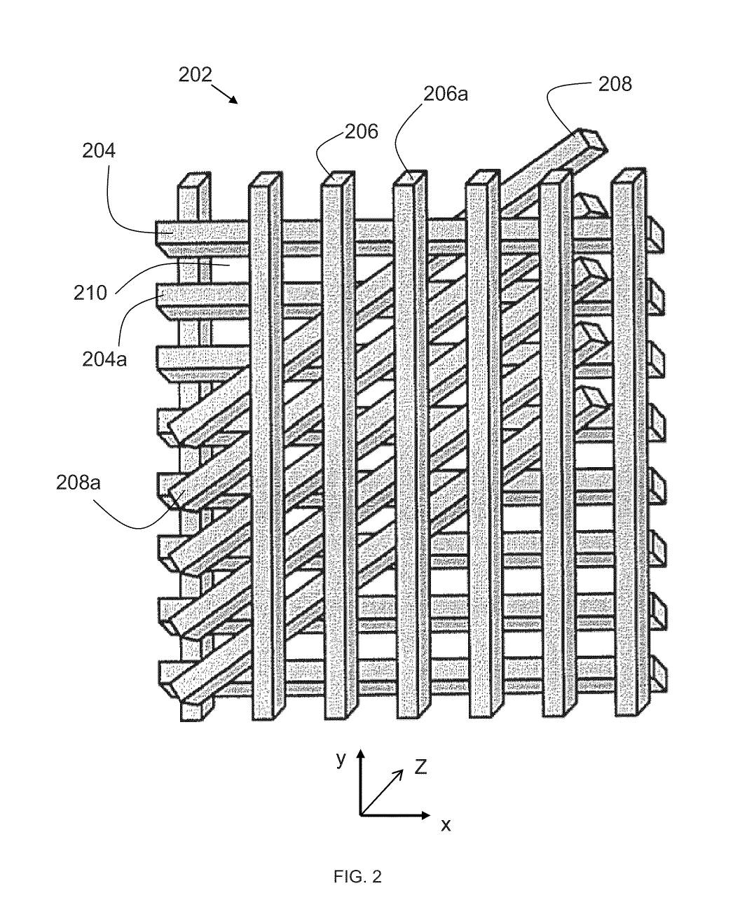

FIG. 2 is a conceptual illustration of a crisscross geometry that minimizes the exciton diffusion distance needed before encountering an interface between an electron conducting material and a hole conducting material. A three-dimensional lattice structure 202 is formed by linear channels, which may be either electron or hole conducting channels. Typically in a polymer solar cell, the linear channels are electron acceptor/carrier materials. Linear channels 204, 204a extend along the X axis (left to right in FIG. 2) and form a spaced parallel array along the Y axis (top to bottom in FIG. 2). Linear channels 206, 206a form a similarly spaced parallel array, extending in the Y direction, and spaced along the X axis. A third set of linear channels 208, 208a also form an evenly spaced parallel array, but extend in the Z direction (into the paper in FIG. 2) and at an oblique angle to the channels 204 and 206 (cornerwise in FIG. 2). The channels are illustrated as being rectangular, but may be any elongated shape, including cylindrical, as in a shape of a carbon nanotube. They may be individual components or etched from a larger block. They may be woven together, i.e., crossing on one side of some channels and another side of other channels.

For ease of description, the X axis will be assumed to be the direction of incoming light, but the configuration can be adapted to any incident angle of light. In one preferred embodiment, the channels parallel to the direction of incoming light (204) are of a larger diameter than those extending across the incoming tight, to lessen interference of the transverse channels with light absorption. For example, different diameters of nanotubes may be used in different directions.

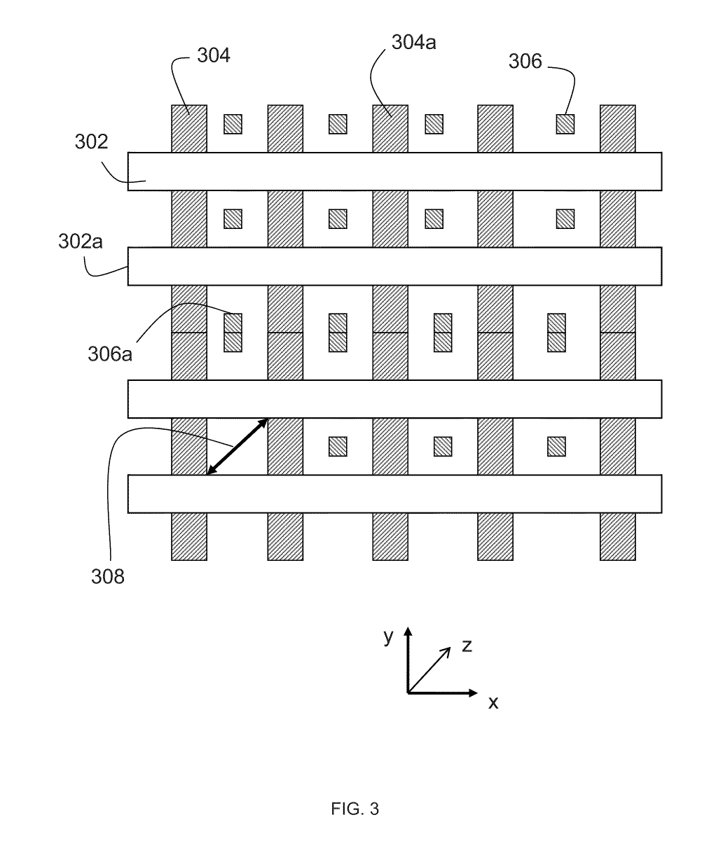

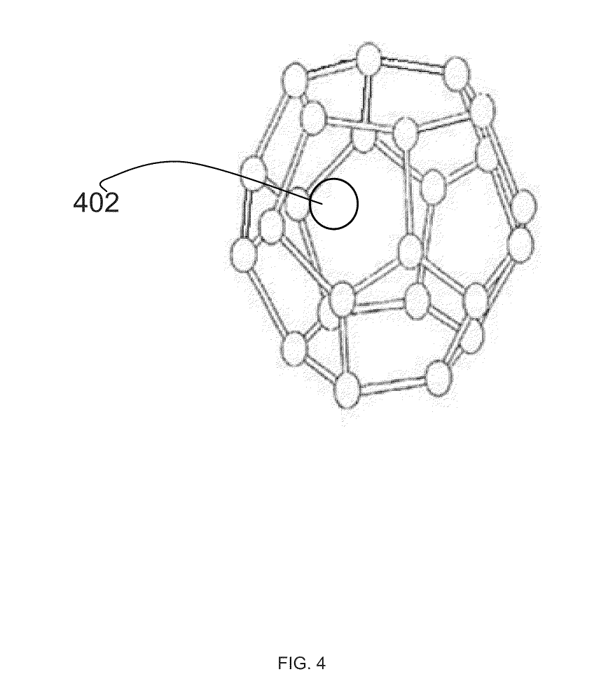

FIG. 3 shows another embodiment of the present crisscross configuration, where the channels 302, 302a extend along the X axis and form a parallel array by being spaced apart spaced along the Y axis; similarly, channels 304, 304a extend perpendicularly to the channels 302, 302a and extend along the Y axis forming a parallel array by being spaced apart along the X axis; and channels 306, 306a extend perpendicularly along the Z axis (into the paper in FIG. 3) and are parallel in the X and Y directions. In FIG. 3 and FIG. 4 (discussed below in connection with clathrates), the arrays shown are illustrated in two dimensions, but are arrayed in three dimensions. That is, there are parallel channels hidden behind the channels shown. This configuration is apparent with regard to the channels 306, 306a, but applies also to the other channels. It can be seen that the light incoming along the X axis will strike transverse elements 304 and 306. It is contemplated that these elements occupy minor portions of the space, which is filled by the exciton generating material, which may be viewed as occupying channels formed between elements 306.

The dimensions of the channels are selected to allow significant exposure of the matrix material to the incoming light, while allowing for short exciton pair travel distance. As shown by arrow 308, the opening where light will strike the matrix material may be enlarged by using different dimensions and/or spacings for different channel members.

### Channels

The linear channels 204, 206, 208 or 302, 306, 306 may be either electron or hole conducting channels; the space between them is occupied by the opposite material, either hole or electron conducting, respectively.

The channel serves the functions of accepting and transporting to an electrode a member of an exciton pair. A channel may be formed from a nanotube (e.g. single walled carbon nanotube, SWNT, or multiwalled carbon nanotube, MWNT), nanorod, or nanowire. The individual channel members preferably have a diameter less than 200 nanometers (typically about 2-30 nm) and a length at least ten times their diameter (a condition referred to as “quasi-one dimensional,” in that the aspect of length greatly exceeds width or diameter). The channel may also be formed of parylene (acceptor), nanorods of group II-IV compounds, such as nanorods of CdSe, strings of quantum-dot (acceptor), or strings of nanoparticles of CuInSe₂.

MWNTs particularly useful as linear channels may be synthesized by the standard arc technique as described in Ebbesen et al. U.S. Pat. No. 5,641,466 issued Jun. 24, 1997. They are generally produced by one of three techniques, namely electric arc discharge, laser ablation and chemical vapor deposition. Using plasma enhanced chemical vapor deposition, vertically aligned carbon nanotubes can easily be grown. In these chemical vapor deposition processes, the catalyst decomposes the hydrocarbon gas to produce carbon and hydrogen. The carbon dissolves into the particle and precipitates out from its circumference as the carbon nanotube. Thus, the catalyst acts as a ‘template’ from which the carbon nanotube is formed, and by controlling the catalyst size and reaction time, one can easily tailor the nanotube diameter and length respectively to suit. Carbon tubes, in contrast to a solid carbon filament, will tend to form when the catalyst particle is ˜50 nm or less because if a filament of graphitic sheets were to form, it would contain an enormous percentage of ‘edge’ atoms in the structure. Alternatively, nanotubes may be prepared by catalytic pyrolysis of hydrocarbons as described by Endo, et al., in J. Phys. Chem. Solids, 54, 1841 (1993), or as described by Terrones, et al., in Nature, 388, 52 (1997) or by et al., in Chem. Mater., 8, 2190 (1996), the contents of all of which are incorporated by reference for describing nanotube preparation.

The bonding in all carbon nanotubes is sp², with each atom joined to three neighbors, as in graphite. The tubes can therefore be considered as rolled-up graphene sheets (graphene is an individual graphite layer). There are three distinct ways in which a graphene sheet can be rolled into a tube.

The first two of these, known as “armchair” and “zig-zag” have a high degree of symmetry. The terms “armchair” and “zig-zag” refer to the arrangement of hexagons around the circumference. The third class of tube, which in practice is the most common, is known as chiral, meaning that it can exist in two mirror-related forms. The various structures determine the conductivity of the nanotube, which may be “metallic” or semiconducting. The present device preferably uses nanotube channels which are semiconducting.

Possible nanowires for use as the present channels include aluminum nanowires, e.g., Ono et al. “Magnetic orderings in Al nanowires suspended between electrodes,” Applied Physics Letters—Jun. 23, 2003—Volume 82, Issue 25, pp. 4570-4572; those described in Geng et al. “Synthesis and optical properties of S-doped ZnO nanowires,” Synthesis and optical properties of S-doped ZnO nanowires,” Applied Physics Letters—Jun. 30, 2003—Volume 82, Issue 26, pp. 4791-4793; “Self-assembled growth of epitaxial erbium disillicide nanowires silicon (001)” by Yong Chen, Douglas A. A. Ohlberg, Gilberto Medeiros-Ribeiro, Y. Austin Chang, and R. Stanley Williams in Applied Physics Letters, 76, p. 4004, June 2000, and silicon nanowires as described in Englander et al., “Local synthesis of silicon nanowires and carbon nanotubes on microbridges,”Applied Physics Letters—Jun. 30, 2003—Volume 82, Issue 26, pp. 4797-4799.

Nanowires may also be formed of CuI. A suitable extended compound is shown in Haddleton et al, “First structurally authenticated inorganic polymers of CuBr and CuI containing chiral bidentate N-donor ligands Use of the Schiff base 2,2°-bis[(4S)-4-benzyl-2-oxazoline] as ligand,” New J. Chem., 1998, Pages 315-317. The crystal packing diagram for Cu₂I₂L is described as a ribbon or stair, and may serve as a conducting channel formed inside a molecular void compound in the present design.

Nanorods may also be carbon (see, e.g., Science 10 Sep. 1999: Vol. 285. no. 5434, pp. 1719-1722); metal oxide (see U.S. Pat. No. 6,036,774); silicon carbide (see U.S. Pat. No. 5,997,832); metals and metal alloys such as copper, nickel and gold, see. e.g., Salem et al. “Multi-component nanorods for vaccination applications,” Nanotechnology 16 484-487, 2005.

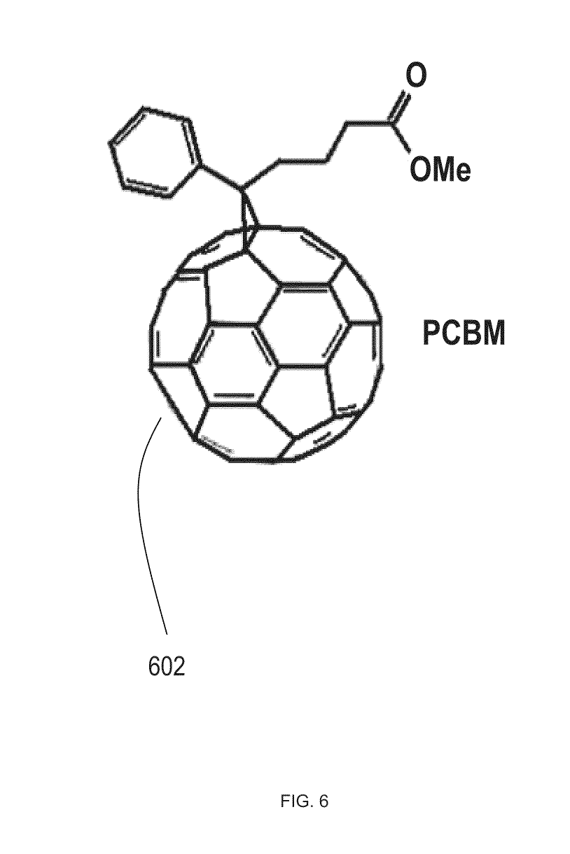

Other channels may be made from PCBM ([6,6]-phenylen C61-butyric acid methyl ester), a fullerene derivative. Its structure is shown in FIG. 6 at 602.

### SWNT Channels

Single walled nanotubes (SWNTs) are particularly preferred for use in the present invention, and in particular in a lateral or orthogonal relation to the incoming light. SWNTs can be produced by laser vaporization (LV), electric-arc vaporization (AV) and by chemical vapor deposition (CVD). The LV and AV methods produce loose nanotubes, which are grown in the gas-phase from co-vaporized carbon and approximately 1% catalyst metal. CVD utilizes thermal decomposition of a mixture of carbon-containing and metal-catalyst-containing precursor gases (e.g., methane and ferrocene) above a hot substrate.

In a preferred embodiment, the linear channels 204-208 or 304-308 are an array of semiconducting single walled carbon nanotubes (SWNTs), SWNTs, although predominantly having a single wall, are understood to include instances within a given sample of tubes having multiple walls in some cases. See, Flauhaut et al., “Synthesis of single-walled carbon nanotube-Co—MgO composite powders and extraction of the nanotubes,” J. Mater. Chem., 2000, vol. 10, no 2, pp. 249-252.

The SWNTs serve as electron carriers and may be filled on the interior or linked on the exterior surface to a hole-carrying polymer such as Poly (3-Hexylthiophene), i.e., P3HT. This polymer is a type of polythiophene, which results from the polymerization of thiophenes, a sulfur heterocycle that can become conducting when electrons are added or removed from the conjugated π-orbitals via doping. C60 and other graphitic materials may be used as electron acceptor channels.

### Matrix Material

The material in the present device which absorbs light and in response generates an exciton (i.e., a bound electron/hole pair) is referred to as the matrix material. It is typically an organic polymer. The particular matrix material used will be chosen to be compatible with the channel material. Exemplary matrix materials include poly(2-methoxy-5-(3′,7′-dimethyloctyloxy)-1,4-phenylene-vinylene), an organic polymer commonly referred to as MDMO-PPV. Poly (e-hexylthiophene), an organic polymer commonly referred to as P3HT, is useful in that incident light is absorbed mainly over the wavelength range 450 nm to 600 nm. Another organic material that may be employed is 3,4,9,10-perylenetetracarboxylic-bis-benzimidazole (PTCBI). The actual thickness of the organic polymer absorber must be very thin, on the order of about 100 to 150 nm. One may also use polymers based on copper iodine chains. By using a co-crystal scaffolding, poly(diiododiacetylene), or PIDA, can be prepared as a nearly unadorned carbon chain substituted with only single-atom iodine side groups. The monomer, diiodobutadiyne, forms co-crystals with bis(nitrile) oxalamides, aligned by hydrogen bonds between oxatamide groups and weak Lewis acid-base interactions between nitrites and iodoalkynes. In co-crystals with one oxalamide host, the diyne undergoes spontaneous topochemical polymerization to form PIDA. Further details are set forth in Sun et al., “Preparation of poly(diiododiacetylene), an ordered conjugated polymer of carbon and iodine,” Science, 2006 May 19; 312(5776):1030-4. Conducting PIDA may be formed inside clathrate host molecules and used as conducting channels, while the clathrate forms a photovoltaic matrix material.

A further listing of donor and acceptor materials useful in the present invention is found in Kietzke, “Advances in Organic Solar Cells,” Advances in OpioElectronics, Volume 2007, Article ID 40285, published on line, which presents the following table:

TABLE 1

| Donor | Acceptor | η | VOC | FF | IPCE |
|---|---|---|---|---|---|
| CuPc | C60 | 5.7% | 1.0 V | 59% | NA |
| CuPc | C60 | 5.0% | 0.6 V | 60% | 64% |
| MeO-TPD, ZnP-(stacked) | C60 | 3.8% | 1.0 V | 47% | NA |
| CuPc | C60 | 3.5% | 0.5 V | 46% | NA |
| DCVST | C60 | 3.4% | 1.0 V | 49% | 52% |
| CuPc | PTCBI | 2.7% | 0.5 V | 58% | NA |
| SubPc | C60 | 2.1% | 1.0 V | 57% | NA |
| MeO-TPD, ZnPc | C60 | 2.1% | 0.5 V | 37% | NA |
| TDCV-TPA | C60 | 1.9% | 1.2 V | 28% | NA |
| Pentacene on PET | C60 | 1.6% | 0.3 V | 48% | 30% |
| SnPc | C60 | 1.0% | 0.4 V | 50% | 21% |

### Lattice Construction

In order to construct the lattice, different deposition/orientation methods are effective, including nanostructure alignment via fluid flow, applied electric fields, applied magnetic fields, and thermal gradients. This serves to align channel elongated structures in various directions, and may also be used to orient channel members formed from smaller structures into aggregates. Carbon nanotubes have been shown to become magnetized when placed in contact with magnetic material.

To deposit a single aligned layer, polymers may be patterned on a substrate, and the pre-formed nanotubes flowed across the substrate at a concentration and rate whereby they stick to the polymer in a defined orientation. Another method of “activating” the substrate is to use an electron beam from a scanning electron microscope to form chemically reactive spots or lines, as described in T. D. Yuzvinsky, A. M. Fennimore, A. Kis and A. Zettl, “Controlled placement of highly aligned carbon nanotubes for the manufacture of arrays of nanoscale torsional actuators,” Nanotechnology 17, 434-438 (2006). Another method of placing a nanostructure in a predefined position is described in US 2004/0005723 to Empedocles, et al., published Jan. 8, 2004, entitled “Methods of making, positioning and orienting nanostructures, nanostructure arrays and nanostructure devices.” Described there are methods of forming nanowires (or any other small or one-dimensional structure, e.g., a nanodot, nanoribbon, nartotetrapod, etc.) and corresponding arrays with any of a variety of properties by patterning nanostructure catalysts and/or precursors on a substrate. Nanostructure catalysts and/or precursors are heated, melting into spheres that influence the eventual diameter and location of nanostructures made from the spheres.

An effective method for aligning nanotubes, nanowires, nanorods, etc., is via the application of external electric or magnetic fields. The anisotropic dielectric or magnetic susceptibility of these nanostructures renders them orientationally sensitive. The nanostructures may be suspended in a fluid while the field is applied; the fluid is then removed (by evaporation or other means) and the nanostructures are fixed in place within a binder or by direct attachment to the substrate. DC and AC fields are both effective for this process. Alignment of nanostructures using electric fields is described in Yuegang Zhang et al., Appl. Phys. Lett. 79, 3115 (2001); K. Yamamoto, S. Akita, and Y. Nakayama, Jpn. Appl. Phys. Part2, 35, L917 (1996); K. Yamamoto, S. Akita, and Y. Nakayama, J. Phys. D. 31, L34 (1998); X. Q. Chen, I. Saito, H. Yamada and K. Matsushige, Appl. Phys. Lett. 78, 3714 (2001); Larry A. Nagahara, Islamshah Amlani, Justin Lewenstein, and Raymond K. Tsui, Appl. Phys. Lett. 80, 3826 (2002).

As a specific three-dimensional construct on example using mechanical (fluid flow shear) forces, nanotubes suspended in a fluid polymer binder are spin-cast onto a suitable substrate. The spin casting aligns the nanotubes and, as the polymer solvent evaporates, the nanotubes are fixed into position. The substrate is then rotated, and the spin-casting process repeated. The second nanotube layer is then mis-aligned with the first. The process is repeated, with successively advancing orientation angle. Thus, a three-dimensional network of the conducting nanowires is generated with the desired optimal geometrical configuration.

Alternatively, a nanostructure for use in the present invention may be formed directly from the substrate by photolithographic and etching techniques. It would then have the composition of the substrate layer from which it was formed.

### Void-Bearing Molecules for Forming or Containing Channel Like Structures

In an alternative embodiment, void bearing molecules may be used as frameworks for assembling the channels, or may be used to form the channels themselves. Preferred void bearing molecules are clathrates. The term “clathrate,” from the Greek word khlatron meaning barrier, indicates crystalline inclusion compounds in which small guest atoms or molecules are physically trapped in host cavities shaped by a three-dimensional assembly of hydrogen bonded molecules. These compounds are traditionally clathrate hydrates when they contain water and gas hydrates when the enclosed molecules are gases; the latter are much more commonly encountered. According to the size of the trapped molecule; three types of structures are observed: cubic I [1], cubic II[2] and hexagonal H [3]. These structures correspond to different arrangements of the water. In the present case, the clathrate compound will contain water a guest molecule, which is an electron channel, or will itself be an electron channel.

FIG. 4 shows a clathrate as described, for example in U.S. Pat. No. 6,797,199 to Eguchi, et al. issued Sep. 28, 2004, entitled “Clathrate compounds, manufacture thereof, and thermoelectric materials, thermoelectric modules, semiconductor materials and hard materials based thereon.” which contemplates a clathrate compound which displays promise as a high efficiency thermoelectric material, meeting the three conditions of a low thermal conductivity, a high Seebeck coefficient and a high electrical conductivity. This clathrate comprises a clathrate lattice with atoms of at least one element from Group 4B of the periodic table (Ti, Zr, Hf, Rf) as the main structure, doping atoms which are encapsulated within the lattice spacing of the clathrate lattice, and substitution atoms which are substituted for at least one portion of the atoms which make up the clathrate lattice. Doping atoms of the clathrate compound are also taught. Suitable clathrates may also include silicon clathrate 46 (Si₄₆), which is a mixed lattice of a Si₂₀ cluster comprising a dodecahedron of Si atoms, and a Si₂₄ cluster comprising a tetradecahedron of Si atoms. One may also use silicon clathrate 34 (Si₃₄), which is a mixed lattice of a Si₂₀ cluster comprising a dodecahedron of Si atoms, and a Si₂₈ cluster comprising a hexadecahedron of Si atoms. Also suitable are: carbon clathrate 46 (C₄₆), which is a mixed lattice of a C₂₀ cluster comprising a dodecahedron of C atoms, and a C₂₄ cluster comprising a tetradecahedron of C atoms; and carbon clathrate 34 (C₃₄), which is a mixed lattice of a C₂₀ cluster comprising a dodecahedron of C atoms, and a C₂₈ cluster comprising a hexadecahedron of C atoms. Silicon clathrate compounds are further described in U.S. Pat. No. 5,800,794 to Tanigaki et al., entitled “Clathrate compounds and processes for production thereof.”

FIG. 4 illustrates that the three dimensional clathrate structure comprises a number of polyhedrons, and each polyhedron may contain a guest atom or structure 402. Where the polyhedrons are symmetrically arranged, extended channel structures may extend through the clathrate voids.

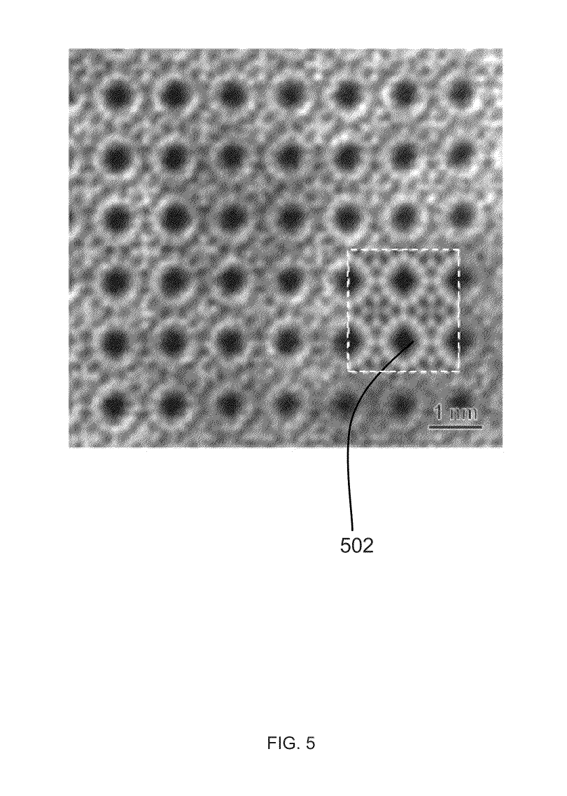

FIG. 5 illustrates a two dimensional representation of a void bearing molecule, wherein an array of multiple pores can be seen. These pores may be used for contain channels, as shown at 502. In the particular image shown, the ring pattern and the center of the ring correspond to the Si₂₄ cage and the 6d sites, respectively. The 6d sites are aligned in an atomic column, which is apart from the nearest columns by 0.23 nm so that the Na occupancy in the 6d sites can be determined by comparing the experimental intensity profiles with calculated ones. As described above, one may employ clathrates with a mesoporous structure, based on a typical exciton diffusion distance of about 20 nm, where the clathrate itself is the channel. Techniques for designing pores of different sizes are disclosed in Soler-Illia et al., “Chemical Strategies to Design Textured Materials: from Microporous and Mesoporous Oxides to Nanonetworks and Hierarchical Structures,” Chem. Rev. 102:4093-4138 (2002) mesoporous pore sizes may be between 2 and 50 nm. Where the clathrate merely provides a framework for channels such as silicon nanowires, which may be linear arrays of Si₂₄ and Si₂₀ cages, the pore size need only accommodate the channels, since not every pore will be filled with channel. The polymer or electron donor will also be intimately associated with the clathrate structure.

Preferred clathrate molecules are the framework silicates. These can form a variety of structures, and are comprised in many minerals. See, Smith J V 1978 Enumeration of 4-connected 3-dimensional nets and classification of framework silicates, II, Perpendicular and near-perpendicular linkages from 4.8(2), 3.12 (2) and 4.6.12 nets, Am. Mineral. 63 960-969. One embodiment uses zeolites. The zeolites are framework silicates consisting of interlocking tetrahedrons of SiO₄ and AlO₄. In order to be a zeolite the ratio (Si+Al)/O must equal 1/2. The alumina-silicate structure is negatively charged and attracts the positive cations that reside within. Unlike most other tectosilicates, zeolites have large vacant spaces or cages in their structures that allow space for large cations such as sodium, potassium, barium and calcium and even relatively large molecules and cation groups such as water, ammonia, carbonate ions and nitrate ions. In the more useful zeolites, the spaces are interconnected and form long wide channels of varying sizes depending on the mineral. These channels allow the easy movement of the resident ions and molecules into and out of the structure.

As described more fully “Clathrate compounds and methods of manufacturing,” WO2007047952, clathrates are composed of a covalently bonded framework, which forms “polyhedra” that can encapsulate guest atoms inside. The cited patent publication pertains to type II clathrate materials that have the general form AₓE₁₃₆ (0<x<24), in which represents the atoms forming the framework of the structure, and A represents the guest atoms contained inside the framework polyhedra. In this structure, there are two distinct polyhedra that form the building blocks of the structure, denoted E₂₀ (twenty vertices at which the E atoms reside; sixteen E₂₀ cages per conventional unit cell of E₁₃₆) and E₂₃ (twenty-eight vertices at which the E atoms reside; eight E₂₈ per E₁₃₆), and their size and the local environment of the guest atom inside is distinctly different. The crystal structure of the type II clathrate consists of structural units AₓE₁₃₆ in which E represents the atoms forming the framework of the structure, and A represents the guest atoms contained inside the framework polyhedra. As further described in WO2007047952, E can include, but is not limited to Si, Ge, or Sn, and A includes, but is not limited to Na, K, Rb, Cs, Ca, Sr, Ba, or Eu. The method of WO2007047952 allows the control of the various structural aspects of the type II clathrate structure, in order to control and/or optimize the material's physical properties for photovoltaic applications. The manipulation of the band gap, carrier (or doping) concentration and photo-electric efficiency are described therein.

Aluminum oxide (alumina) may be used to form channels for electron carrying channels when formed as in a membrane filter, which has a sieve-like structure. The material may be etched across the sieve pores, Suitable synthesis methods are described in Liu et al., “Synthesis of mesoporous aluminum oxide with aluminum alkoxide and tartaric acid,” Materials Letters Volume 42, Issue 3, January 2000, Pages 143-149.

Also, metal organic frameworks (MOF) may be used as channel forming structures. For example, Kramer et at, “Synthesis and properties of the metal-organic framework Mo3(BTC)2 (TUDMOF-1),” J. Mater. Chem., 2006, 16, 2245-2248, disclose that a porous metal-organic framework, Mo3(BTC)2 (BTC=1,3,5-benzene-tricarboxylate) was obtained by oxidation of Mo(CO)6 with trimesic acid. The compound is microporous and has a high specific micropore volume (0.67 cm3 g-1) and BET surface area (1280 m2 g-1). Another suitable method for producing an MOF is disclosed in US 2007/0227898 by Muller, et al., published Oct. 4, 2007, entitled “Method for Electrochemical Production of a Crystalline Porous Metal Organic Skeleton Material.” Other MOFs comprise Zn²⁺ as a metal ion and ligands derived from terephthalic acid as the bidentate compound, are particularly preferred. Said framework materials are known as MOF-5 in the literature. The prototypical MOF-5 is built up by Zn₄O groups on the corners of a cubic lattice, connected by 1,4-benzenedicarboxylic acid (alternatively known as terephthalic acid). Another preferred ligand is 1,3,5-benzene tricarboxylate (BCT). Further preferred ligands are ADC (acetylene dicarboxylate), NDC (naphthalene dicarboxylate), BDC (benzene dicarboxylate), ATC (adamantane tetracarboxylate), BTC (benzene tricarboxylate), BTB (benzene tribenzoate), MTB (methane tetrabenzoate) and ATB (adamantane tribenzoate). These may be prepared according to U.S. Pat. No. 6,617,467 to Muller, et al., issued Sep. 9, 2003, entitled “Process for producing polyalkylene carbonates.”

Other MOB useful in the present design include MOF-74, a matrix composed mainly of carbon and zinc.

### Conclusion

The above specific description is meant to exemplify and illustrate the invention and should not be seen as limiting the scope of the invention, which is defined by the literal and equivalent scope of the appended claims. Any patents or publications mentioned in this specification are intended to convey details of methods and materials useful in carrying out certain aspects of the invention which may not be explicitly set out hut which would be understood by workers in the field. Each one of such patents or publications, even though not individually specifically so identified, are intended to be and hereby are incorporated by reference to the same extent as if each was specifically and individually set forth in full, as needed for the purpose of describing and enabling the method or material referred to in the context of the claimed invention.

What is claimed is:

1. An excitonic solar cell having heterojunction between donor and acceptor semiconductor materials, wherein one semiconductor material is in the form of a matrix material and the other semiconductor material is in the form of a nanoscate channel material contacting an electrode, wherein:
said nanoscale channel material extends through the matrix material as separated channel elongated structures along three dimensions, termed an X axis, a Y axis and a Z axis, to minimize diffusion distance to a channel elongated structure of a member of an exciton pair formed in the matrix material by incoming light.

2. The excitonic solar cell of claim 1 wherein the channel elongated structures are formed of materials selected from the group consisting of carbon nanotubes, nanowires, semiconductor nanorods, including semiconductor nanorods, carbon nanorods, fullerene and fullerene derivatives.

3. The excitonic solar cell of claim 2 wherein the channel elongated structures are formed of materials comprising carbon nanotubes, wherein the carbon nanotubes comprise single walled carbon nanotubes.

4. The excitonic solar cell of claim 2 wherein the channel elongated structures are formed of materials comprising semiconductor nanorods, wherein the semiconductor nanorods comprise CdSe.

5. The excitonic solar cell of claim 1 wherein the channel elongated structures comprise void bearing molecules.

6. The excitonic solar cell of claim 5 wherein the void bearing molecules provide structural support to the channel elongated structures.

7. The excitonic solar cell of claim 5 wherein the void bearing molecules comprise flu channel elongated structures.

8. The excitonic solar cell of claim 5 wherein the bearing molecule is selected from the group consisting of metal-organic frameworks (“MOF”), zeolites, silicon clathrates including Si₃₄, Si₂₄ and Si₄₆, and carbon clathrates including C₄₆, C₂₄, C₂₈ and C₃₄.

9. The excitonic solar cell of claim 8 wherein the MOF comprises a metal selected from the group consisting of Zn, Cu and Ti.

10. The excitonic solar cell of claim 9 wherein the MOF comprises 1,4-benzenedicarboxylate (MOF-5).

11. The excitonic solar cell of claim 1 wherein the matrix material is selected from the group consisting of poly(2-methoxy-5-(3′,7′-dimethyloctyloxy)-1,4-phenylene-vinylene), (MDMO-PPV), Poly(3-Hexylthiophene) (P3HT), 3,4,9,10-perylenetetracarboxylic-bis-benzimidazole (PTCBI), and poly(diiododiacetylene) (PIDA).

12. The excitonic solar cell of claim 1 wherein the nanoscale channel material along the three dimensions, including an X axis, a Y axis and a Z axis, is of two different diameters in two different dimensions.

13. The excitonic solar cell of claim 12 wherein the nanoscate channel material comprises at least one of MWNT and SWNT.

14. The excitonic solar cell of claim 1 wherein both the matrix material and the nanoscale channel material are formed from polymers.

15. A method of making an excitonic solar cell comprising channel members, comprising:
aligning the channel members by applying to a fluid composition of the channel members an external electromagnetic field which orients the channel members in a defined direction; and
solidifying the fluid composition to fix the channel members in the defined direction.

16. The method of claim 15 wherein the aligning and the solidifying are repeated in different defined directions.

17. The method of claim 15 further comprising:
suspending the channel members in a fluid while the field is applied;
removing the fluid; and
fixing the nanostructures in place within a binder.

18. The method of claim 15 wherein the electromagnetic field comprises a direct current (DC) field.

19. The method of claim 15 wherein the channel members are selected from the group consisting of nanotubes, nanowires, and nanorods.

20. The excitonic solar cell of claim 2 wherein the fullerene derivatives comprise [6,6]-phenylen C61-butyric acid methyl ester (PCBM).

21. The excitonic solar cell of claim 2 wherein the channel elongated structures are formed of materials comprising carbon nanotubes, wherein the carbon nanotubes comprise multiwalled carbon nanotubes.

22. The excitonic solar cell of claim 2 wherein the channel elongated structures are formed of materials comprising semiconductor nanorods, wherein the semiconductor nanorods comprise fullerene derivatives.

23. The excitonic solar cell of claim 22 wherein the fullerene derivatives comprise [6,6]-phenylen C61-butyric acid methyl ester (PCBM).

24. The excitonic solar cell of claim 6 wherein the void bearing molecules comprise the channel elongated structures.

25. The excitonic solar cell of claim 6 wherein the bearing molecule is selected from the group consisting of metal-organic frameworks (“MOF”), zeolites, silicon clathrates including Si₃₄, Si₂₄ and Si₄₆, and carbon clathrates including C₄₆, C₂₄, C₂₈ and C₃₄.

26. The method of claim 15 further comprising:
suspending the channel members in a fluid while the field is applied;
removing the fluid; and
fixing the nanostructures in place by direct attachment to the substrate.

27. The method of claim 16 further comprising:
suspending the channel members in a fluid while the field is applied;
removing the fluid; and
fixing the nanostructures in place within a binder.

28. The method of claim 16 further comprising:
suspending the channel members in a fluid while the field is applied;
removing the fluid; and
fixing the nanostructures in place by direct attachment to the substrate.

29. The method of claim 15 wherein the electromagnetic field comprises an alternating current (AC) field.

30. The method of claim 16 wherein the electromagnetic field comprises a direct current t (DC) field.

31. The method of claim 16 wherein the electromagnetic field comprises an alternating current (AC) field.

32. The method of claim 16 wherein the channel members are selected from the group consisting of nanotubes, nanowires, and nanorods.
